(19) United States
(12) Patent Application Publication
(10) Pub. No.: US 2018/0035548 A1
(43) Pub. Date: Feb. 1, 2018

(54) PATTERNED LAYER COMPOUND

(71) Applicant: Fraunhofer-Gesellschaft zur Foerderung der angewandten Forschung e.V., Munich (DE)

(72) Inventors: Christof LANDESBERGER, Graefelfing (DE); Dieter BOLLMANN, Muenchen (DE); Waltraud HELL, Muenchen (DE); Gerhard KLINK, Fuerstenfeldbruck (DE)

(21) Appl. No.: 15/660,721

(22) Filed: Jul. 26, 2017

(30) Foreign Application Priority Data
Jul. 28, 2016 (DE) 102016213878.2

(51) Int. Cl. H05K 3/30; H05K 3/00; H05K 1/18; H05K 1/05

(52) U.S. Cl. CPC H05K 3/305; H05K 1/056; H05K 3/0011; H05K 3/0044; H05K 1/181; H05K 2201/10674; H05K 2203/107

(57) ABSTRACT

The invention relates to a method in which a layer compound having a substrate having an adhesive layer applied thereon at least in regions is provided. An opening extending through the substrate and through the adhesive layer is introduced therein in order to obtain a patterned layer compound. A microchip having an active region arranged on the outside of the chip is provided, wherein the active region is a sensor area or a radiation coupling-out area. In addition, in accordance with the invention, the microchip is arranged on the adhesive layer of the patterned layer compound such that the active region is exposed through the opening.

### CROSS-REFERENCE TO RELATED APPLICATION

This application claims priority from German Patent Application No. 10 2016 213 878.2, which was filed on Jul. 28, 2016, and is incorporated herein by reference in its entirety.

### BACKGROUND OF THE INVENTION

The invention relates to a method for manufacturing a microchip arranged on a patterned layer compound, comprising the features of claim 1, and to a package for a microchip comprising the features of claim 23.

Many sensors use an opening in the package in order to be able to measure a parameter of the environment, like air pressure, air humidity, gases, flow, particle measurement, radiation measurement, etc. For sensors based on semiconductor devices (“chips” or “microchips”), this means that the chip package (“package”) needs to have an opening to the surroundings/atmosphere. Since sensitive surfaces of a semiconductor sensor are frequently very small, i.e. <1 mm², realizing a precise opening above the sensor area is frequently very difficult or complicated. Frequently, the package results in the sensor housed to be bulky or big. However, for many applications, miniaturization or extreme flatness of the sensor device housed is an important requirement.

This applies, for example, for sensors which are to be integrated in portable electronics, like smartphones. Another critical problem results from the fact that an opening in the package results in the chip elements to fail when water or humidity penetrates, except when the contact regions (contact pads, wire bonds) are encapsulated completely.

Consequently, it would be desirable to realize a sensor package for chip elements which allows extremely small structural heights, like considerably below 1 mm, and which seals all electronic components, except for the sensitive area, from humidity and other influences hermetically.

FIGS. 13 and 14 show an example of a conventional pressure sensor package 1000. An MEMS element 1001 which comprises the pressure-sensitive membrane and a respective ASIC 1002 which recalculates and communicates to the outside the measurement signal to form pressure values, are mounted on a small base plate 1003 and comprise wire bonds 1004 for contacting among one another and to the circuit board. As in shown in FIG. 14, the chips 1001, 1002 are covered on the mounting plate 1003 by a lid 1005 (like a metal sheet) comprising an opening 1006 in order for the surrounding pressure to be also measurable within the chamber of the MEMS element.

It is understandable that humidity/water can penetrate through the opening of the package 1006 with such structures, resulting in short circuits of the wiring within. The height of the wire bond also contributes to the structural height of the entire package.

Flip-chip mounting techniques for semiconductor devices on films or other substrates (PCB, printed circuit boards) are also known; see, for example, the publication: Rekha S. Pai, Kevin M. Walsh, “The viability of anisotropic conductive film as a flip chip interconnect technology for MEMS devices”, J. Micromech. Microeng. 15 (2005) 1131-1139. This publication describes how an ACA (anisotropic conductive adhesive) is used for flip-chip mounting a pressure sensor above an opening in a circuit board (circuit carrier). It becomes obvious from the description and the images that the ACA or ACF (anisotropic conductive film) material is applied on the side of the sensor chip and, after that, the chip is placed above the hole. In addition, only the chip area with the contact pads is covered by the ACA/ACF material. Applying the ACA/ACF material on the chip side is difficult and, with ever smaller chip sizes (below 1 mm), this entails a precise mechanical process.

U.S. Pat. No. 8,177,355 B2 describes cutting an ACF film by means of a laser. Column 4, line 55 mentions ACF laser cutting. What is described is that the ACF is patterned by means of the laser and, subsequently, the ACF patterned already is mounted on a substrate.

### SUMMARY

According to an embodiment, a method may have the steps of: providing a layer compound having a substrate having an adhesive layer applied thereon at least in regions, introducing an opening extending through the substrate and the adhesive layer in order to obtain a patterned layer compound, providing a microchip having an active region arranged on the outside of the chip, wherein the active region is a sensor area or a radiation coupling-out area, and arranging the microchip on the adhesive layer of the patterned layer compound such that the active region is exposed through the opening.

According to another embodiment, a package for a microchip may have: a film substrate having a contact area for electrical chip contacting, an adhesive layer applied onto the film substrate and covering the contact area at least in portions, and a microchip having an active region arranged on the outside of the chip, wherein the microchip is in contact with the adhesive layer at least in portions, wherein the film substrate and the adhesive layer have a joint continuous opening, and wherein the microchip is arranged on the adhesive layer such that the active region is exposed through the opening.

In accordance with the inventive method, a layer compound comprising a substrate having an adhesive layer applied thereon at least in regions is provided. In the sense of the present disclosure, the substrate including the adhesive layer applied thereon is referred to as a layer compound. In accordance with the invention, an opening which extends through the substrate and the adhesive layer is introduced into this layer compound. The process of introducing the opening in the sense of the present disclosure is also referred to as patterning. The layer compound comprising the continuous opening thus is also referred to as a patterned layer compound. In addition, a microchip is provided in accordance with the invention. The microchip comprises an active region arranged on the outside of the chip. When, for example, the microchip is a sensor chip, the active region may be a sensor area. The microchip, however, may also comprise an emitter for emitting (for example electromagnetic) radiation, like an LED or the like, for example. In this case, the active area may be a radiation coupling-out area. The active area may also be referred to as effective area since the respective desired effect is achieved in the region of this area. In accordance with the invention, the microchip is arranged on the adhesive layer such that the active region of the microchip is exposed through the opening provided in the layer compound. Advantageously, the active region is not covered by the adhesive layer and thus is in contact with the surroundings by the opening. A medium to be measured (like gases, liquids, etc.) or radiation (like light) may, for example, propagate through the opening to the active region of the microchip and/or flow towards the active region. On the other hand, when the active region is a radiation coupling-out area, the radiation coupled out may be released to the surroundings through the opening. Advantageously, the entire area of the active region is arranged within the cross-section of the opening, i.e. the adhesive does not come into contact with the active region of the microchip. However, it would also be feasible for the adhesive to contact portions of the active region at least partly. This may, for example, occur when the adhesive is liquid and flows to a certain extent in the direction of the active region of the microchip. The adhesive can seal the microchip, except for the active region, and protect the same from humidity, dust, dirt, etc., for example. However, the active region will be freely accessible through the opening, at least with its part not covered by the adhesive, i.e. the medium to be measure or radiation to be measured or emitted may enter and exit through the opening. Advantageously, the microchip is arranged such that the active region is oriented to be symmetrical to the opening, i.e. the edge of the active area has the same distance to the edge of the opening. Among others, the inventive method offers the advantage that applying the adhesive or adhesive layer at the location of the future chip placement on the substrate may involve a great tolerance. Fewer process steps are used for manufacturing the microchip arranged on the patterned layer compound than with a conventional structure. This is cost and time-saving and the process security is increased. Additionally, the adhesive provides for the opening to be sealed from humidity and/or dirt penetrating. Patterning the layer compound, i.e. introducing a joint continuous opening in the substrate and the adhesive can take place relatively easily and at increased tolerance. In well-known chip manufacturing methods, like flip-chip bonding methods, for example, in contrast, the adhesive is patterned before and only applied on the substrate after that. With other known flip-chip bonding methods, the adhesive is applied on the chip and the chip has to be arranged precisely with the (usually conductive) adhesive applied on the electrical contacts of the substrate, such that a sensor area is at the same time oriented precisely above an opening in the substrate. The tolerances in known methods consequently are much smaller, which in turn entails precise processing, which in turn results in increased process costs.

In accordance with an embodiment, the microchip may be arranged on the adhesive layer of the patterned layer compound such that the active region, in a top view on the opening, is completely within the projection of the cross-sectional area of the opening. Thus, the entire active region at the outside of the chip remains completely accessible from outside, i.e. through the opening. Furthermore, it can be ensured that the entire active region is utilized, for example in order to provide the largest sensor area or radiation coupling-out area possible.

It is conceivable for patterning the substrate and the adhesive layer to be done in a joint process step. This is suitable when the adhesive layer has already been applied on the substrate. Thus, the opening is introduced into the substrate and into the adhesive layer jointly and/or at the same time. This saves time in manufacturing when compared to conventional methods where an ACF material is patterned separately from the substrate. In accordance with the invention, the positioning of the opening here may be done in dependence on the contact area for the chip contacting on the substrate or adjusting mark manufactured in relation with metal structures on the base substrate. Arranging the microchip may also be done in dependence on the contact areas or adjusting marks. In this way, the geometrical tolerances between the opening in the substrate and chip placement are kept at a minimum.

In accordance with an embodiment of the inventive method, the microchip may be arranged on the layer compound by means of an anisotropic conductive adhesive layer (ACA or ACF) using a flip-chip mounting technique. The anisotropic conductive adhesive layer here may be arranged on the substrate such that the anisotropic conductive adhesive layer contacts the substrate and a contact area, provided on the substrate, for electrically contacting the microchip. Such flip-chip mounting techniques including an ACA or ACF material are suitable for mass production and are able to shorten the clock times considerably when compared to conventional methods.

It is conceivable for the adhesive layer, after curing, to form a hermetic seal of the contact area between the microchip and the substrate. Hermetic sealing in particular means a water and dirt-tight sealing, or gas-tight sealing. This is of particular advantage when compared to conventionally packaged sensors where humidity can penetrate through the unprotected package opening and shorten electrical contacts.

It is conceivable for the adhesive layer to comprise a non-conductive adhesive, in particular an epoxide adhesive, wherein the electrical chip contacting is provided by means of thermo-compression bonding methods or by means of soldering. Non-conductive adhesives are cheaper and easier to handle than conducting adhesives, wherein the process costs can be reduced for mass production.

It is conceivable for the adhesive layer to be cured thermally after arranging the microchip on the adhesive layer. The thermo-activator adhesives employed here are highly suitable for being used in an inventive method, since these adhesives can be applied precisely on the substrate, without curing before being activated thermally.

In accordance with another embodiment, introducing the opening in the substrate and the adhesive layer may be done by means of laser patterning. Laser patterning or laser cutting is of advantage in that no shear forces are entailed for introducing the opening. This is of advantage when the substrate is a film, for example.

It is conceivable here for laser patterning to be done by means of short-pulse laser or by means of ultra-short-pulse lasers or by means of laser beams at wavelength of less than 400 nm, i.e. ultra-violet light. Short-pulse lasers are lasers emitting laser beams intermittently in the nanosecond range. Ultra-short-pulse lasers are lasers emitting laser beams intermittently in the piko or femtosecond ranges. Premature undesired thermo-activation of the adhesive can be avoided by such short-pulsed lasers.

In accordance with an embodiment of the inventive method, introducing the opening into the substrate and the adhesive layer may be done by means of a mechanical stamping process or by means of drilling. This is particularly suitable when using conventional PCBs (circuit boards) made of epoxide resin and the like. Drilling and stamping are very easy and quick methods for introducing the opening into the layer compound (substrate and adhesive).

It is feasible for the substrate to be a film having a thermo-stability of up to 300° C. Such films are of particular advantage when using thermally activatable glues, since these films keep their structures without any damages even when applying high temperatures.

In accordance with conceivable embodiments, the substrate may be a film made of polyimide (PI), polyethylene terephthalate (PET), polyethylene phtalate (PEN), polycarbonate, paper, polyether ether ketone (PEEK) or epoxide. With such film substrates, the structural height of a package (layer compound of film substrate and adhesives including the microchip) can be reduced considerably when compared to conventional PCBs made of epoxide resin and the like.

It would also be conceivable for the substrate to be a metal film which comprises an insulation layer arranged between the same and a contact area provided on the substrate. A metal film exhibits high stability and, at the same time, great flexibility. An insulation layer is arranged between the metal film and the contact area for electrically contacting the microchip in order to avoid short-circuiting.

It is conceivable for the substrate, the adhesive layer and the microchip connected thereto to exhibit an overall thickness between 50 μm and 500 μm. This is of particular advantage with electric sensorics to be mounted into mobile devices, like smartphones and the like. Such an overall thickness may be realized using the inventive method in a reproducible manner. Conventionally packaged sensors, in contrast, exhibit a thickness of 1 mm or more.

The adhesive layer may be applied on the substrate in a paste-like stated, wherein the adhesive layer is pre-dried before introducing the opening. Adhesives in a paste-like state are easy to handle and process. For example, an ACA film may be provided as a paste-like material which is applied onto the substrate and pre-dried subsequently. The joint opening in term is introduced into the ACA layer and the substrate, advantageously in a joint process step.

It is conceivable for the substrate to be a circuit board and to comprise at least one material from the group of glass, ceramics, plastics or epoxide. Such substrates are easy to produce and, in addition, relatively stable and heat-resistant so that processing and implementing the inventive method using these substrates may be done easily.

It is conceivable for the adhesive layer to be applied on the substrate such that the adhesive layer on the substrate covers an area which is larger by between 50 μm and 1 mm than the border of the contact area of the microchip which the microchip contacts the adhesive layer by. Consequently, applying the adhesive layer may be done at a relatively great tolerance, i.e. the adhesive area need not necessarily have the same size as the area of the microchip. In addition, this ensures that, on the one hand, the microchip is connected securely to the adhesive layer and, on the other hand, a good sealing effect relative to dirt and humidity is achieved.

In accordance with an embodiment, a window film having a recess can be provided, wherein the window film is arranged on the patterned layer compound such that the microchip is arranged within the recess, wherein the recess is filled at least partly by a potting compound. Thus, the window film forms a package where the microchip is arranged. Advantageously, the height of the window film exceeds that of the microchip. By means of the potting compound, the entire microchip packaged within the recess (window) of the window film in turn can be sealed hermetically, thereby protecting the entire microchip from dirt and humidity.

Another film or coating made of a polymer, glass or metal may, for example, be arranged on that side of the window film facing away from the substrate for covering the recess provided in the window film.

It is conceivable for the microchip to be a sensor chip configured to measure at least one of air pressure, temperature, humidity, gas, gas components, liquid flow or gaseous flow by means of the active region, or wherein the microchip is a sensor chip for a fluidic system, a biosensor chip or a capacitive sensor chip contactable by a liquid or gas. Furthermore, it is conceivable for the sensor chip to be useable also for measuring a pH value in a liquid, or as an amperometrical electrode or for measuring a potential in a fluidic surrounding.

In accordance with another embodiment, the microchip may be a sensor chip configured to measure radiation, particularly light, by means of the active region. The sensor chip may, for example, be a photo diode, wherein the photo sensor is arranged above the opening in the substrate and the adhesive layer so that light incident through the opening may be detected by the sensor area.

Additionally, the microchip may be configured to emit radiation, particularly light, by means of the active region. In this case, the active region is a radiation coupling-out area which is arranged above the opening in the substrate and the adhesive layer so that radiation can be emitted through the opening. Exemplarily, LEDs may be used here, the light exit area of which is placed above the opening so that LEDs can emit light to the outside through the opening.

A further aspect of the invention provides a package for a microchip, wherein the package comprises, among other things, a film substrate having a contact area for electrical chip contacting and an adhesive layer applied onto the substrate and covering the contact area at least in portions. In addition, the package comprises a microchip having an active region arranged on the outside of the chip, wherein the microchip contacts the adhesive layer at least in portions. In accordance with the invention, the substrate and the adhesive layer comprise a joint continuous opening and the active region of the microchip is arranged on the adhesive layer to be exposed through the opening. Such a package offers the advantage that the microchip, except for the active area which may, for example, be a sensor area or a radiation coupling-out area, is sealed hermetically and thus protected from humidity and/or dirt penetrating. Particularly, the electrical contacts are sealed by means of the adhesive layer so that short-circuiting can be avoided.

### BRIEF DESCRIPTION OF THE DRAWINGS

Embodiments of the invention are illustrated in the drawings and discussed below, in which:

FIG. 1A shows a block diagram of an inventive method,

FIGS. 1B-1E show cross-sectional views of a representational device for discussing method steps of the inventive method,

FIG. 1F shows a top view on a device for discussing the projection area of the opening provided in the substrate,

FIGS. 2-6 show further cross-sectional views of a representational device for discussing method steps of the inventive method,

FIGS. 7-9 show side views on an inventive device,

FIG. 10 shows a top view on a layer structure having an adhesive applied and an opening extending through the layer structure,

FIG. 11 shows a view on the lower side of a layer structure with an opening extending through the layer structure,

FIG. 12 shows another cross-sectional view of a representational device for discussing a method step of the inventive method,

FIG. 13 shows a cross-sectional view of a well-known chip package, and

FIG. 14 shows a top view on a known sensor chip package covered by a cover having an opening.

### DETAILED DESCRIPTION OF THE INVENTION

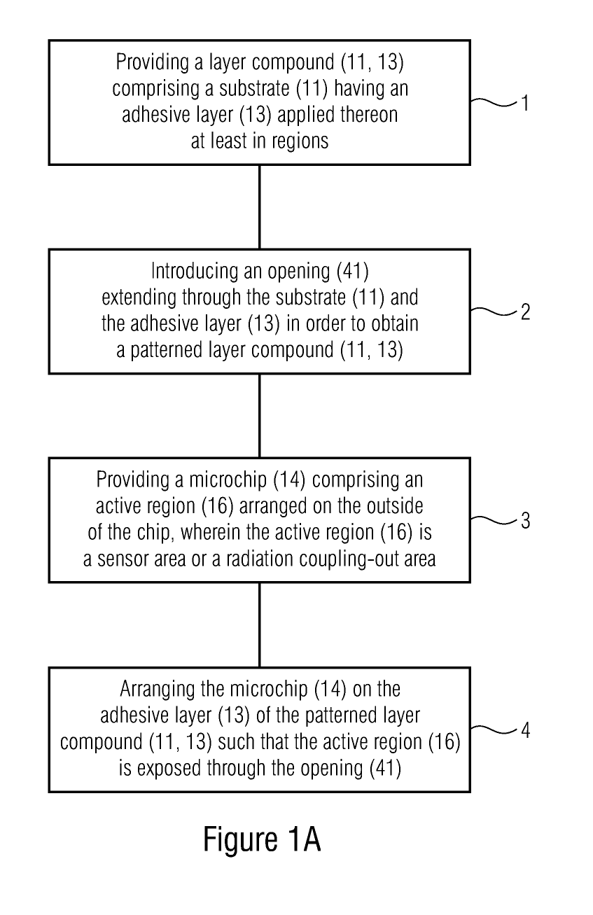

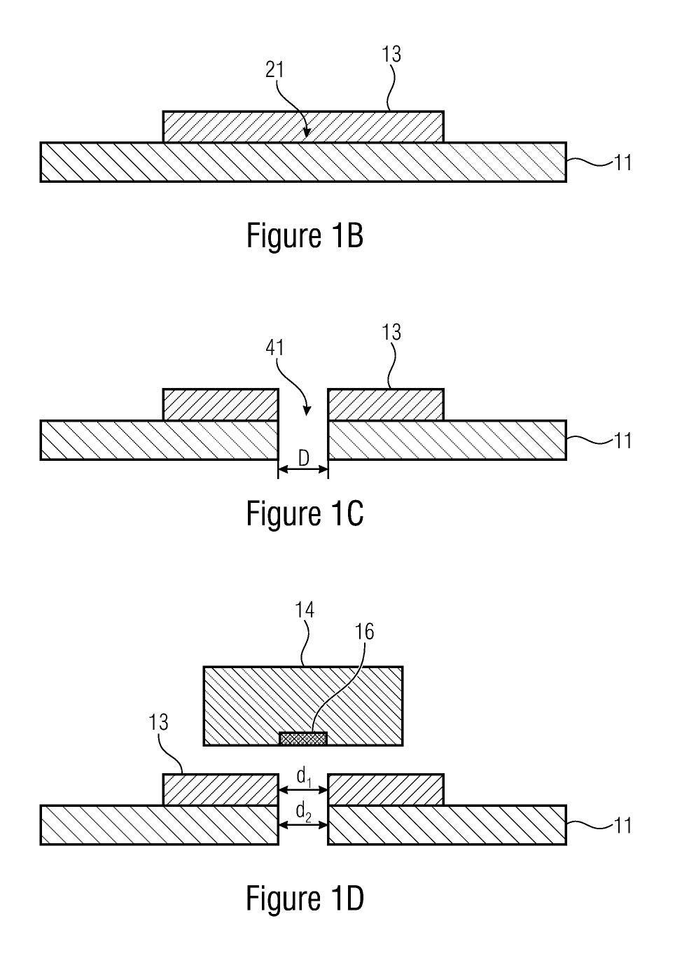

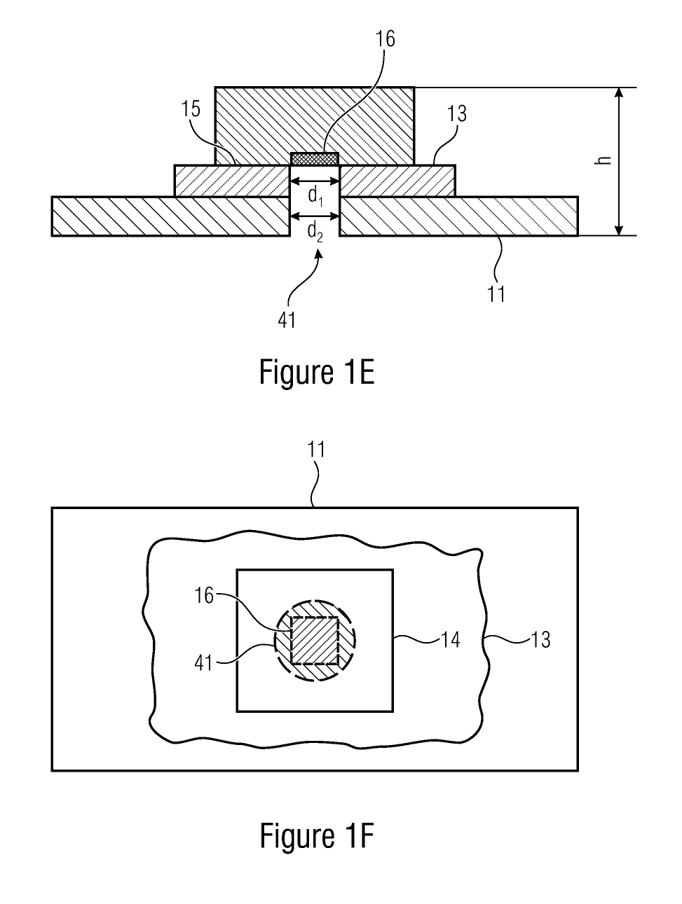

FIG. 1A shows a block diagram for the progress of an inventive method which basically consists of four steps. The individual steps may also be executed in an order differing from that illustrated in FIG. 1A.

In block 1, a layer compound 11, 13 comprising a substrate 11 having an adhesive layer 13 applied at least in portions thereon is provided.

In block 2, an opening 41 extending through the substrate 11 and the adhesive layer 13 is introduced in order to obtain a patterned layer compound 11, 13.

In block 3, a microchip comprising an active region arranged on the outside of the chip is provided. The active region may be a sensor area or a radiation coupling-out area.

In block 4, the microchip is arranged on the adhesive layer. Thus, the microchip is arranged on that side of the adhesive layer facing away from the substrate. The microchip is arranged on the adhesive layer such that the active region is exposed through the opening.

FIGS. 1B to 1E show a representational progress of the inventive method.

A substrate 11 is illustrated in FIG. 1B. An adhesive layer 13 is applied on the substrate 11. The adhesive layer 13 extends over the substrate 11 at least in portions. However, the adhesive layer 13 may also extend completely over the entire substrate 11. The substrate 11 and the adhesive layer 13 applied thereon form a layer compound 11, 13.

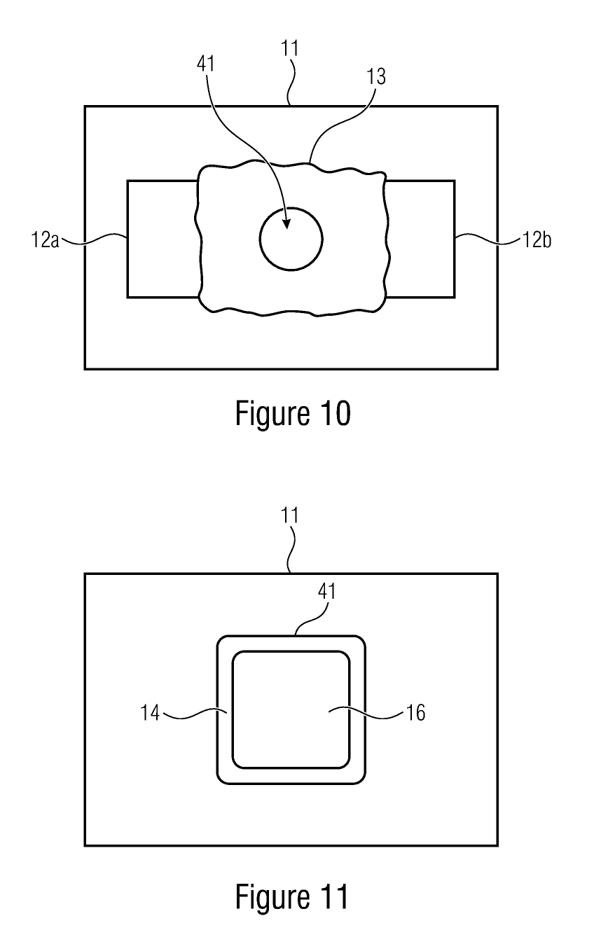

It is to be recognized in FIG. 10 that an opening 41 is introduced into the layer compound 11, 13. The layer compound 11, 13 is also patterned. The result is a patterned layer compound 11, 13. The opening 41 extends completely through the substrate 11 and the adhesive layer 13.

Advantageously, the opening 41 here extends perpendicularly to a direction of extension of the substrate 11.

A microchip 14 is provided in FIG. 1D. The microchip 14 comprises an active region 16 on its outside. The active regions 16 may be a sensor area. However, the active region 16 may also be a radiation coupling-out area.

It may be recognized from FIG. 1E how the microchip 14 is arranged on the layer compound 11, 13. The microchip 14 is arranged on the adhesive layer 13 such that the active region 16 is exposed through the opening 41. The active region 16 thus is in contact with the surroundings at least in portions. In the embodiment shown in FIG. 1E, the active region 16 is exposed completely through the opening 41, i.e. the entire active region 16 is in contact with the surroundings.

Expressed differently, the microchip 14 is arranged on the adhesive layer 13 of the patterned layer compound 11, 13 such that the active region 16, in a top view on the opening 41, is within the projection of the cross-sectional area of the opening 41. This is to be discussed in greater detail referring to FIG. 1F.

FIG. 1F shows a top view on the patterned layer compound 11, 13 with the microchip 14 arranged thereon. The adhesive layer 13 may be recognized on the substrate 11. The microchip 14 is arranged on the adhesive layer 13.

In the top view shown, the microchip 14 hides the opening 41 and the active region 16 from being visible, which is why these two elements 41, 16 are illustrated in broken lines. However, it can be recognized that the active region 16 with its entire area (hatching from the top right to the bottom left) is arranged within the projection of the cross-sectional area of the opening 41 (hatching from the top left to the bottom right). As can be recognized in FIG. 1F, the cross-sectional area of the opening 41 means a cross-section along the direction of extension or plane of the substrate 11.

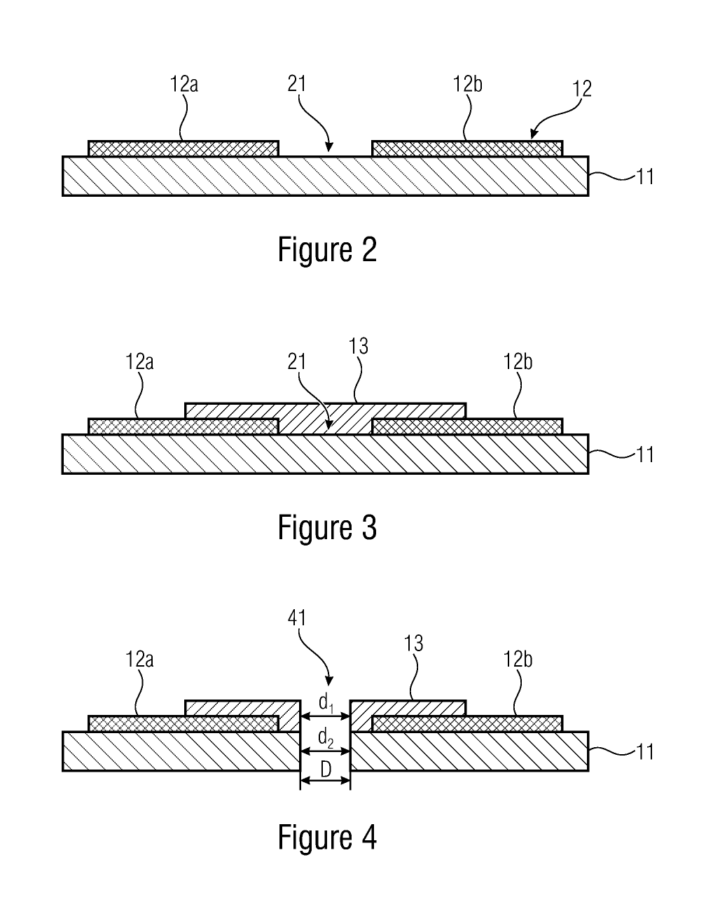

Another representational embodiment for visualizing an inventive method is shown in FIGS. 2 to 6.

A substrate 11 is shown in FIG. 2. The substrate 11 comprises a contact area 12 for electrical chip contacting. The contact area 12 in the embodiment illustrated is implemented to be a two-part area having a first area part 12a and a second area part 12b. These area halves 12a, 12b of the contact area 12 not connected to each other electrically may, for example, be used as a plus pole and minus pole for contacting a microchip.

The substrate 11 may also comprise more than one contact area 12. In addition, the one or several contact areas 12 in turn may comprise more than the two contacts 12a, 12b mentioned above.

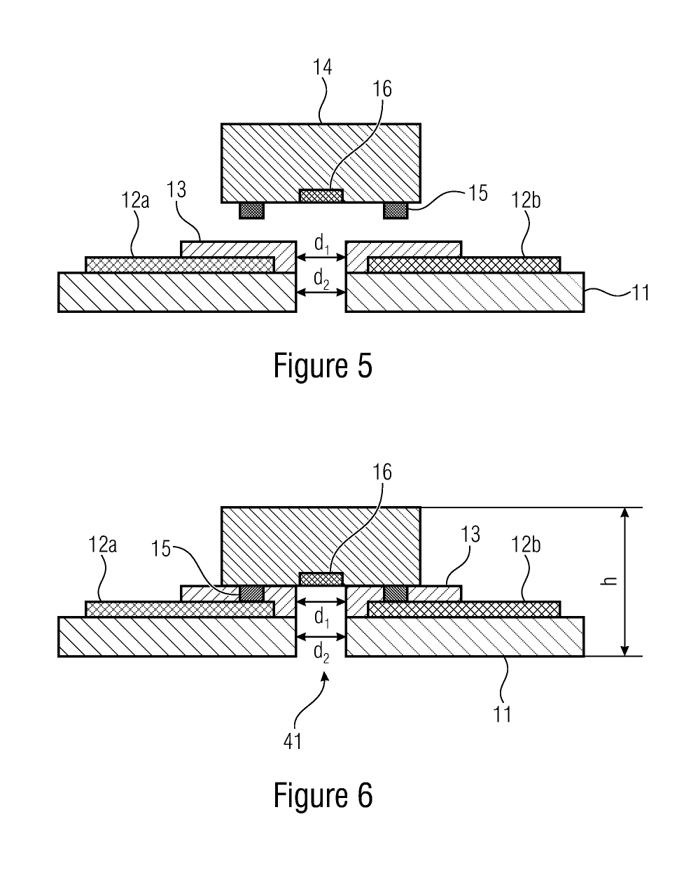

The contact area 12 may be pre-patterned. Exemplarily, there may be a distance of a certain size between the two area halves 12a, 12b so that a gap 21 forms between the two area halves 12a, 12b. The distance or clear width of this gap 21 may be adapted already to the size of an active area 16 of a microchip 14 to be arranged thereon later. This will be described below in greater detail referring to FIGS. 5 and 6.

FIG. 3 additionally shows an adhesive applied 13. The adhesive layer 13 is applied onto the substrate 11 and the contact area 12 such that the adhesive layer 13 contacts the substrate 11 at least in portions and the contact area 12 at least in portions 12. In the present embodiment, the adhesive layer 13 is applied at the position of the gap 21 mentioned before between the two contact area halves 12a, 12b. Thus, the adhesive layer 13 advantageously covers the gap 21 completely.

As is shown in FIG. 4, the substrate 11 and the adhesive 13 are patterned together. Here, an opening 41 which extends through the substrate 11 and through the adhesive 13 is introduced into the layer compound 11, 13. Advantageously, this is performed in a joint process step.

For further illustration of the opening 41 in the layer compound 11, 13, reference here is made to FIG. 10. FIG. 10 shows the layer compound 11, 13 in a top view. The adhesive layer 13 is applied on the substrate 11 with the two contact area halves 12a, 12b. The opening 41 extends completely through the adhesive layer 13 and through the substrate 11.

A microchip 14 is illustrated in FIG. 5. The microchip 14, on the outside of the chip, comprises an active region 16. The active region 16 may, for example, be implemented as an active area extending on the outside of the microchip 14. The microchip 14 may, for example, be a sensor microchip and, in this case, the active area 16 would be a sensor area which may come into contact with the medium to be detected. However, the microchip may also be a radiation-emitting element. In this case, the active area 16 would be a radiation coupling-out area able to emit radiation towards the outside. Expressed more generally, the active region 16 is an effective region or effective area within which there is an effect, like detecting a medium, detecting radiation, in particular electromagnetic radiation, or emitting radiation, in particular electromagnetic radiation, like light, for example.

In this embodiment, the microchip 14 also comprises contacts 15 for electrically contacting the microchip 14 with the contact areas 12a, 12b of the substrate 11. The contacts 15 here may be contacted electrically with the contact areas 12a, 12b of the substrate 11 directly or indirectly (like by means of ACA or ACF).

As can be seen in FIG. 6, the microchip 14 is arranged on the adhesive layer 13 such that the active region 16, in a top view on the opening 41, is within the projection of the cross-sectional area of the opening 41 at least in portions.

FIG. 11 shows a view on the substrate 11 from below for further illustration. What can be recognized is the opening 41 extending through the substrate 11 and the adhesive layer 13. As can be seen, the opening 41 need not to be of a round shape. In the embodiment illustrated, for example, it is quadrangular.

When looking through the opening 41 from below, the microchip 14 and the active region 16 thereof can be recognized. In the embodiment illustrated, the active region 16 is completely within the projection of the cross-sectional area of the opening 41. More precisely, the active region 16 is symmetrical within the opening 41. This means that the active region 16, which only exemplarily is illustrated to be quadrangular, comprises the same distance on all four sides to the four sides of the exemplarily quadrangular opening 41.

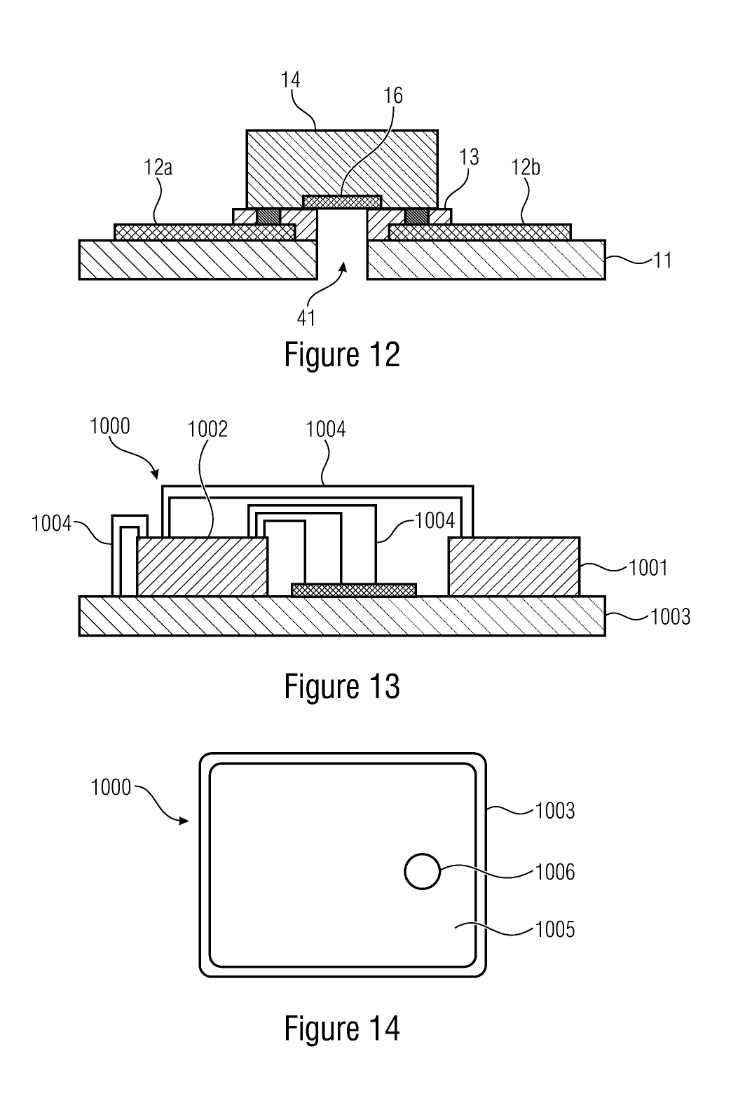

FIG. 12 shows another embodiment where the active region 16 of the microchip 14 is exposed through the opening 41 at least in portions. The area of the active region 16 here is larger than the cross-sectional area or the diameter (or outer dimensions) of the opening 41. Correspondingly, in a top view, the active region 16 overlaps the opening 41 at least in portions. It is also conceivable for the active region 16 to overlap the opening 41 only on one side. In accordance with the invention, in a top view on the opening 41, the active region 16 is within the projection of the cross-sectional area of the opening 41 at least in portions.

Thus, it is conceivable for the active region to be arranged within the projection of the cross-sectional of the opening 41 by at least 80% of its overall area, advantageously to be arranged within the projection of the cross-sectional area of the opening 41 by at least 90%, and more advantageously at least 95% and, even more advantageously, completely.

In some embodiments, patterning the substrate 11 and the adhesive layer 13 takes place in a joint process step. This means that the opening 41 is introduced into the substrate 1 and the adhesive layer 13 in one and the same process step.

Introducing the opening 41 may, for example, be performed by means of etching methods, laser methods or by means of mechanical methods. Exemplarily, a wet or dry-etching method may be used in order to provide the opening 41 in the substrate 11 and the adhesive layer 13. It would be conceivable here for the method steps shown in FIGS. 5 and 6 to be interchanged. This means that the microchip 14 may be arranged on the adhesive layer 13 at first and then the opening 41 be etched. Advantageously, the active region 16 of the microchip 14 is resistant to the etchant used.

However, the opening 41 may also be introduced by means of mechanical methods, like stamping, cutting, sewing or drilling. Since, however, in this case large shear forces may act, this type of patterning is of particular advantage when the substrate 11 is formed from a material of little flexibility. Exemplarily, the substrate 11 may be implemented to be a circuit board made of epoxide resin and the like, or the substrate 11 comprises glass, ceramics or plastics. With this mechanical method, it is advantageous for the opening 41 to be patterned at first in the substrate 11 and the adhesive layer 13 and only then the microchip 14 to be placed on the adhesive layer 13.

In some embodiments, providing the opening 41 may be done by means of laser patterning. In case a thermally activatable adhesive 13 is used, the adhesive 13 is in danger of curing prematurely due to the heat developed by the laser. In order to avoid this, it is of advantage for short-pulse lasers with laser durations in the nanosecond range to be used for laser patterning. It would also be conceivable to use ultra-short-pulse lasers with pulse durations in the piko or femtosecond ranges. Lasers emitting ultra violet laser radiation in a wave length range of 400 nm or less may also be used.

It would also be conceivable here for the method steps shown in FIGS. 5 and 6 to be interchanged. This means that the microchip 14 may be arrange on the adhesive layer 13 at first and then the opening 41 be lasered.

Laser-patterning is of particular advantage when the substrate 11 is flexible and, for example, implemented as a film, since, in contrast to the mechanical processes discussed before, there are no shear forces in laser patterning. The film substrate 11 may, for example, be a film made of polyimide (PI), polyethylene terephthalate (PET), polyethylene phthalate (PEN), polycarbonate, paper, polyether ether ketone (PEEK) or epoxide.

In some embodiments, the film substrate 11 may also be implemented as a metal film. In contrast to plastic films, the metal film is of advantage in that it is more durable and able to withstand larger tensile forces, for example. In order to avoid short-circuiting, however, an insulation layer is arranged between the metal film and the contact areas thereof.

Film substrates 11 are of advantage in that the structural height of the layer compound 11, 13, including the microchip 14 arranged thereon, can be kept very small, which is desirable in particular when being mounted in mobile devices. As is shown in FIG. 6, the layer compound, i.e. the substrate 11 and the adhesive layer 13, including the microchip 14, comprises an overall thickness h between 50 μm and 500 μm.

The adhesive layer 13 may comprise a thermally activatable adhesive. This means that the adhesive layer 13 cures only after introducing heat energy. Correspondingly, in accordance with the invention, the adhesive layer 13 may be applied on the substrate 11 and the contact areas 12a, 12b without the same curing prematurely in air. After applying the adhesive layer 13 and introducing the opening 41, the microchip 14 may be arranged on the adhesive layer 13 applied. Subsequently, the adhesive layer 13 is heated so that the adhesive layer 13 cures and connects the microchip 14 to the substrate 11.

As has already been mentioned above, the adhesive layer 13 may comprise an ACA (anisotropic conductive adhesive) or ACF (anisotropic conductive film) adhesive. These adhesives 13 are usually used in flip-chip mounting, for example with RFID labels.

In accordance with embodiments of the invention, the microchip 14 may also be contacted electrically through the opening 41 in the base substrate 11 by means of an anisotropic conductive adhesive layer (ACA or ACF) in a so-called flip-chip technology. All the contact areas 15 of the microchip 14 are insulated among one another by the ACA/AFA layer and encapsulated in the epoxide matrix of the adhesive 13.

After curing, the adhesive layer 13 forms a hermetic sealing of the contact areas 12a, 12b between the microchip 14 and the substrate 11 around the opening 41. Water penetrating through the opening 41 consequently does not reach to the contact areas 12a, 12b embedded in the adhesive layer 13 and consequently no longer results in short circuits. When using a thin film for the substrate 11, the thickness of the package (substrate 11 with optional contact area 12, adhesive layer 13, microchip 14) becomes considerably smaller than with the previous known technology (with a stable carrier plate and wire bond contacting).

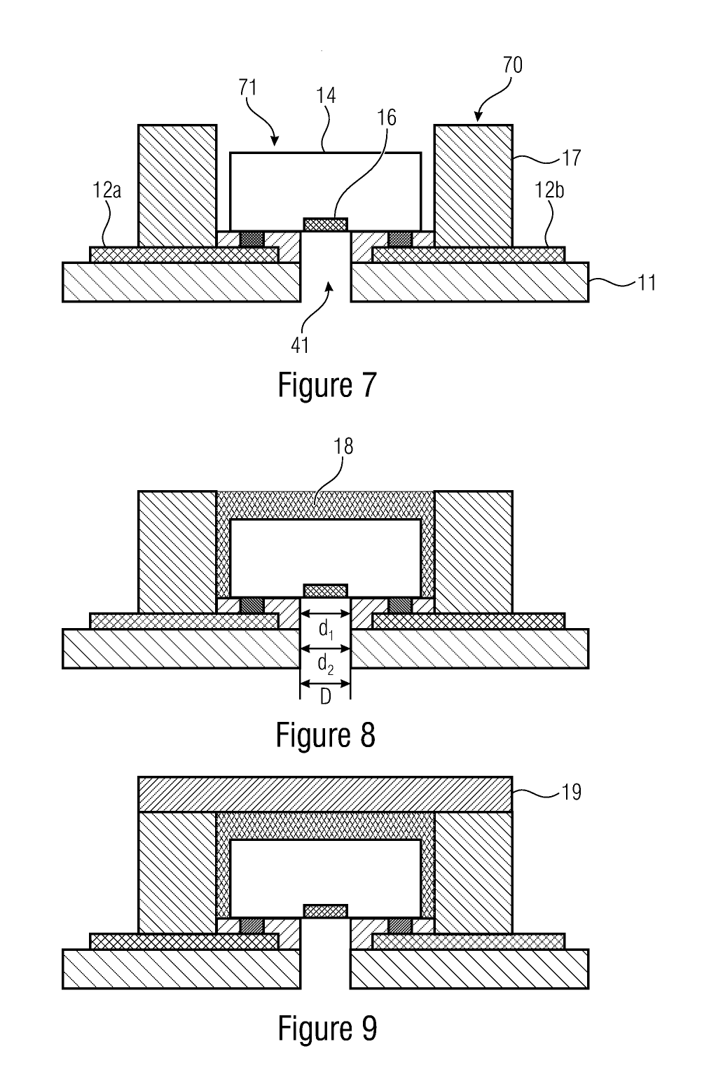

FIGS. 7, 8, and 9 show further steps of the inventive method, wherein the microchip 14 may be packaged.

As is shown in FIG. 7, a window film 17 having a window 71 or recess 71 can be provided. The window film 17 is arranged on the layer compound 11, 13 such that the microchip 14 is arranged within the window 71 or recess 71. In other words, the window film 71 is arranged such that the recess 71 surrounds the microchip 14. In addition, the window film 17 exceeds the microchip 14 in height. As is illustrated in FIG. 7, the window film 17 may be arranged on the contact areas 12a, 12b of the substrate 11. The window film 17 may exemplarily be arranged directly on the substrate 11 or adhesive layer 13.

FIG. 8 shows that the space between the microchip 14 and the recess 71 surrounding the microchip 14 may be filled by a potting compound 18. Thus, a complete hermetic sealing of the microchip 14 may be realized. The potting compound 18 may be ridged or flexible, for example, made of silicone.

The window film 17 may be flexible. However, the stability of the window film 17 is increased considerably by means of filling by the potting compound. After curing of the potting compound, the window film 17 is comparable as regards stability to a package made of a rigid material. Additionally, the window film 17 here is connected fixedly to the microchip 14.

As can be recognized in FIG. 9, another layer, like in the form of another film 19 or coating 19 made of a polymer, glass, ceramics, or metal may be arranged on that side of the window film 17 facing away from the substrate 11 for covering the recess 71 provided in the window film 17.

Thus, using the inventive method, a packaged microchip 14 may be provided, wherein the microchip 14 is hermetically sealed from the outside, except for its active region 16. The adhesive layer 13 arranged around the opening 41 seals the electrical contacts 12a, 12b, 15 from humidity and dirt entering, for example through the opening 41, which may result in short-circuiting. The potting compound 18 filled into the recess 71 of the window film 17, and maybe the additional film or layer 19, seals the microchip 14 hermetically from humidity and dirt penetrating from outside or from above, for example.

Thus, FIGS. 7, 8 and 9 also show an inventive package 70 for a microchip 14. The package 70 comprises a film substrate 11 having contact areas 12a, 12b for electrically contacting the microchip 14.

In addition, the package 70 comprises an adhesive layer 13 applied on the substrate 11. The adhesive layer 13 here covers the contact areas 12a, 12b at least in portions. In particular, the adhesive layer 13 covers those portions of the contact areas 12a, 12b adjacent to the opening 41.

In addition, the package 70 comprises a microchip 14 having an active region 16 arranged on the outside of the chip. The active region 16 may be a sensor area or a radiation coupling-out area.

The microchip 14 is in contact with the adhesive layer 13 at least in portions. In particular, the microchip 14 is in contact with the adhesive layer 13 by at least nearly its entire lower side (i.e. that side facing the substrate 11 or adhesive layer 13), except for its active region 16.

The film substrate 11 and the adhesive layer 13 comprise a joint continuous opening 41 which extends with basically no interruptions through both the film substrate 11 and through the adhesive layer 13.

The microchip 14 is arranged on the adhesive layer 13 or the film substrate 11 such that its active region 16 is exposed through the opening 41. For further details, reference here is made to the above discussions, in particular to FIGS. 6, 11 and 12.

The contact areas 12a, 12b are hermetically sealed around the opening 41 by means of the adhesive layer 13. Thus, humidity and/or dirt penetrating through the opening 41 is avoided from contacting the contact areas 12a and 12b and, possibly, causing a short circuit.

As can, for example, be seen in FIGS. 10 to 1F, 4 to 9 and 12, the joint continuous opening 41 may comprise a cross-section D continuous in the adhesive layer 13 and in the film substrate 11. Alternatively or additionally, the cross-section D may be equal or constant as regards shape and dimension in both the adhesive layer 13 and the film substrate 11.

As can be seen in the Figs, the cross-section d₁ of the opening 41 in the adhesive layer 13 may, for example, basically correspond to the cross-section d₂ of the opening 41 in the film substrate 11. This may, for example, be achieved by the fact that the joint opening 41 is formed in the adhesive layer 13 and the film substrate 11 in a joint method step.

The shape of the joint continuous opening 41 may, for example, be cylindrical. However, it is also conceivable for the opening 41 to comprise a conical shape. In this case, the cross-section or diameter d₁ in the adhesive layer 13 would, for example, be smaller or greater than the cross-section or diameter d₂ in the film substrate 11. The opening 41 may, for example, also be triangular, trapezoidal, conical, frustoconical, pyramidal and the like. Further or different geometrical shapes for the implementation of the opening 41 are also conceivable if these shapes are implemented to be continuous in the adhesive layer 13 and film substrate 11.

The invention is to be summarized below in other words.

In accordance with embodiments of the invention, the microchip 14 (like sensor chip element) is contacted electrically through the opening 41 in the base substrate 11 by means of an isotropic conductive adhesive layer (ACA or ACF) in so-called flip-chip technique. By means of the ACA/ACF layer, all the contact areas 15 of the (for example, MEMS) microchip 14 are insulated among one another and encapsulated in the epoxide matrix of the adhesive 13. Water penetrating no longer results in short circuits. When using a thin film as the substrate 11, the thickness of the package 11, 12, 13, 14 becomes considerably smaller than according to the previous known technology (with a stable carrier plate and a wire bond contacting). The thickness of the chip package up to now has been at least 1 mm.

Previous known structural concepts exhibit the following technical challenges: the hole 41 in the film 11 needs to be adjusted very precisely above the sensitive area 16 of the microchip 14. And: the mounting and contacting adhesive (ACA or ACF) must not cover the sensitive area 16 of the chip 14 (otherwise the sensor function would be impeded).

In order to solve these problems of known technology, an inventive method for manufacturing a microchip 14 arranged on a patterned layer compound 11, 13 is disclosed here. Referring to FIGS. 1B to 9, an exemplary embodiment including flip-chip bonding will be described below.

FIG. 2: substrate 11 with circuit board patterns 12

FIG. 3: ACF film 13 laminated at the position of the future chip placement

FIG. 4: producing a hole 41 in the double layer made of ACF 13 and substrate 11

FIG. 5: adjusting a semiconductor element 14 above the circuit board patterns 12. The microchip 14 (like sensor element) comprises a sensitive or active area 16 and protruding contact pads 15.

FIG. 6: flip-chip bonding of the microchip 14 (like sensor element) on the patterned ACF 13 and substrate 11 including the hole 41

FIG. 7: applying a window film 17 comprising an opening 71 for receiving the microchip 14 (like sensor element). This may take place with no precise adjusting and/or with increased tolerance when positioning.

FIG. 8: (partly or completely) filling the space 71 between the microchip 14 (like sensor element) and the inner frame of the window film 17 by a polymer (potting compound) 18. Thus, the chip package 11, 12, 13, 14, 17 is finished. It would also be possible to omit the step in FIG. 7 and encapsulate the chip backside by a polymer.

FIG. 9: optionally, another layer 19 (film or coating made of polymer, glass or metal) may be applied onto the chip package. In the case of semiconductor elements, light-proof packaging is of advantage. This may be done by sputtering a metal layer.

Embodiments of the inventive solution, among other things, provide for an anisotropic conductive film (ACF) 13 to be applied on the substrate 11 (at this time there is no hole 41) at first and to mechanically fix same by a slight pressure and then to form in a suitable patterning process the hole 41 through the ACF layer 13 and the substrate 11 (like film or thin plate) in only a single process step. In order to fulfill the adjusting requirements of chip placement and contacting, a laser which cuts the hole 41 through the substrate 11 and the ACF layer 13 in a single step is used advantageously. The laser cut here depends on the contact areas 12a, 12b for the chip contacting on the substrate 11, or adjusting marks produced on the base substrate 11 relative to metal structures.

Flip-chip mounting of the microchip 14 (like sensor chip) also depends on the contact areas 12a, 12b or adjusting marks of the metal areas. In this way, the geometrical tolerances between the opening 41 in the substrate 11 and the chip placement are kept at a minimum.

An aspect of the invention is manufacturing a precisely adjusted hole 41 in a double layer of ACF 13 and substrate 11 in only a single method step, like by laser patterning. It is to be kept in mind here that the laser cut does not trigger thermal curing of the ACF material 13 along the laser cutting line. Thermal heating of the surrounding material may be achieved by using a short-pulse laser (pulse duration in the nanosecond range) or ultra-short pulse laser (picoseconds or femtoseconds). Using laser beams with short wavelengths in the ultraviolet range (smaller than 400 nm) reduces the thermal load of the layer to be cut.

Mounting the microchip 14 (like sensor element) by means of an ACF film 13 entails a short-term heat input and pressure. Thus, the ACF film 13 may partly also extend somewhat to towards the inside in the direction of the sensitive or active region 16 of the chip 14. In order to avoid the ACF 13 becoming soft from flowing towards the inside too much, advantageously a certain lead is set between the hole opening 41 in the substrate 11 and the sensitive area 16 on the microchip 14 (like sensor element). How far the ACF 13 may flow towards the inside depends, among other things, on the film thickness thereof and the height of the bumps 15 on the chip 14 or metallization traces 12a, 12b on the substrate 11.

The bumps 15 here act as spacers; they define the minimum distance between the chip 14 and the substrate 11. With higher bumps 15, the ACF layer 13 will flow less towards the inside. Experiments by the inventors have shown that an equal and reproducible flow of the ACF layer 13 may be realized. Thus, this mounting technique is well suitable for encapsulating sensors having an opening to the surroundings.

An alternative to the method for simultaneously producing the opening 41 in the base substrate 11 and the ACF layer 13 may also be a mechanical stamping process. However, this should be implemented such that a good adjusting precision from the edge of the hole to the surrounding metal contact areas 12a, 12b is ensured.

Another embodiment would be drilling a hole through the double layer of substrate 11 and ACF 13. When mounting on a circuit board, this would be of advantage. When mounting on a thin film, however, laser cutting would be of advantage. Cutting using a laser is practically free of forces, which is of particular advantage with thin films and soft adhesive layers. The shear forces when mechanically drilling or stamping, however, may make precise adjusting difficult.

For flat chip packages, using films for the base substrate 11 is of advantage; for example a polyimide film exhibiting a good thermal resistance (up to around 300° C.); however, films made of PET, PEN, polycarbonate, paper, PEEK, epoxide and others may also be used. In addition, metal films provided with an insulating layer (and the metal contact areas 12a, 12b thereon) at least on the side of chip mounting in the region of chip placement, may also be used. When using films as the base substrate 11, the overall thickness of the chip package may be in the range of 50 μm to 500 μm; i.e. considerably thinner than according to known technology.

Furthermore, the base substrate 11 may also be a rigid material, like circuit board, glass, ceramics, plastics or epoxide, for example.

Instead of the ACF layer 13, a layer of a non-conducting adhesive film 13 (like an epoxide adhesive film) may also be applied and subsequently the hole 41 in the adhesive layer 13 and the base substrate 11 manufactured. In this case, a different method may be used for electrical chip contacting. This may, for example, be thermal compression bonding (copper-copper or gold-gold). In addition, the electrical connections to the sensor element may be realized using a soldering process.

Another alternative would be applying an ACF film 13 as a paste-like material, followed by a step of pre-drying the ACA film 13 and then jointly producing a hole through the ACA layer 13 and the base substrate 11.

Up to now, it has not been possible or known to place a microchip 14 (like sensor chip) above an opening 41 in a substrate 11 such that a small sensitive or active area 16 on the (conventionally also very small) chip 14 is placed very precisely below or adjacent to the opening 41 in the substrate 11, wherein the somewhat outside chip contact pads 15 are encapsulated and insulated, and it is ensured at the same time that no mounting or encapsulating adhesive 13 covers the sensitive or active area 16 of the chip 14. The solution approach suggested here (patterning by, for example, laser cutting of two layers 11, 13 in one step) is not obvious for a person skilled in the art since what would be expected is that the laser cut would influence the thermally activatable ACF material 13 along the cutting line thermally such that the epoxide matrix would cure here already. This would prevent future flip-chip bonding. In addition, a person skilled in the art would assume at first that the metal particles in the ACF material 13 impede the laser beam such that no clean cutting line is possible.

An advantage of the laser is the freedom in design for defining the shape of the opening 41; i.e., for example, round, quadrangular, or shaped differently. The opening 41 may in any case be adjusted optimally to the shape of the sensitive or active area 16 on the microchip 14 (like sensor element).

Applying the ACF layer 13 at the position of the future chip placement on the base substrate 11 may be done at great a tolerance. The AC film 13 here may be somewhat greater than the chip 14 itself, like 50 μm to 1 mm larger than the chip border.

Fewer process steps than in a conventional structure are used for manufacturing the package. This is cost and time-saving and increases the process security.

When using films, the package height may be in the range of 50 μm to 500 μm, i.e. considerably flatter than previous chip packages. The packages may even be implemented to be mechanically flexible.

The opening 41 in the package is sealed from humidity or dirt penetrating.

Fields of application are, for example, packages for sensors for air pressure, temperature, humidity, gas, gas components, flows (liquid or gaseous); sensors in fluidic systems, biosensors, capacitive sensors which are in contact with liquids or gases. Even for measuring pH values in liquids or amperometrical electrodes or measuring a potential in a fluid surrounding.

Also of interest for sensors for radiation, like light. In this case, photodiodes would be mounted above an opening in flip-chip technology; even mounting light-emitting elements, like LED elements, for example. Also of interest for electron radiation; any cover of the sensitive layer here would be a relatively strong absorber.

The package may of course contain more than a single chip element. A sensor and an ASIC for data evaluation or an additional element for data transmission, for example, would also be useful.

Although the embodiments described above have been described such that the substrate 11 comprises a planar shape, the substrate 11 may also exhibit different shapes. The substrate 11 may, for example, have a curved shape (like a dome structure) or a shape planar and/or folded in portions.

Although some aspects have been described in connection with a device, it is to be understood that these aspects also represent a description of the corresponding method so that a block or element of a device is to be understood to be also a corresponding method step or feature of a method step. In analogy, aspects having been described in connection with or as a method step also represent a description of a corresponding block or detail or feature of a corresponding device.

The method steps described here may be executed in any different order than that stated in the claims.

While this invention has been described in terms of several embodiments, there are alterations, permutations, and equivalents which will be apparent to others skilled in the art and which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A method comprising:
providing a layer compound comprising a substrate comprising an adhesive layer applied thereon at least in regions,
introducing an opening extending through the substrate and the adhesive layer in order to acquire a patterned layer compound,
providing a microchip comprising an active region arranged on the outside of the chip, wherein the active region is a sensor area or a radiation coupling-out area, and
arranging the microchip on the adhesive layer of the patterned layer compound such that the active region is exposed through the opening.

2. The method in accordance with claim 1, wherein the microchip is arranged on the adhesive layer of the patterned layer compound such that the active region, in a top view on the opening, lies within the projection of the cross-sectional area of the opening.

3. The method in accordance with claim 1, wherein introducing the opening comprises patterning the substrate and the adhesive layer in a joint process step.

4. The method in accordance with claim 1, wherein the microchip is arranged on the layer compound by means of an anisotropic conductive adhesive layer (ACA or ACF) using a flip-chip mounting technique, wherein the anisotropic conductive adhesive layer is applied on the substrate such that the anisotropic conductive adhesive layer contacts the substrate and a contact area provided on the substrate for electrically contacting the microchip.

5. The method in accordance with claim 4, wherein the adhesive layer, after curing, forms a hermetic sealing of the contact area between the microchip and the substrate around the opening.

6. The method in accordance with claim 1, wherein the adhesive layer comprises a non-conducting adhesive, in particular an epoxide adhesive, and wherein the electrical chip contacting is provided by means of a thermo-compression bonding method or by means of soldering.

7. The method in accordance with claim 1, wherein, after arranging the microchip on the adhesive layer, the adhesive layer is cured thermally.

8. The method in accordance with claim 1, wherein introducing the opening into the substrate and the adhesive layer takes place by means of laser patterning.

9. The method in accordance with claim 8, wherein laser patterning is done by means of short-pulse lasers or by means of ultra-short-pulse lasers or by means of laser beams comprising wave lengths of less than 400 nm.

10. The method in accordance with claim 1, wherein introducing the opening into the substrate and the adhesive layer takes place by means of a mechanical stamping process or by means of drilling.

11. The method in accordance with claim 1, wherein the substrate is a film comprising a thermal resistance of up to 300° C.

12. The method in accordance with claim 1, wherein the substrate is a film made of polyimide (PI), polyethylene terephthalate (PET), polyethylene phthalate (PEN), polycarbonate, paper, polyether ether ketone (PEEK) or epoxide.

13. The method in accordance with claim 1, wherein the substrate is a metal film comprising an insulation layer arranged between the same and a contact area provided on the substrate.

14. The method in accordance with claim 1, wherein the substrate and the adhesive layer and the microchip connected thereto together comprise an overall thickness between 50 μm and 500 μm.

15. The method in accordance with claim 1, wherein the adhesive layer is applied onto the substrate in a paste-like state, and wherein the adhesive layer is pre-dried before introducing the opening.

16. The method in accordance with claim 1, wherein the substrate is a circuit board or comprises at least one material from the group of glass, ceramics, plastics or epoxide.

17. The method in accordance with claim 1, wherein the adhesive layer is applied onto the substrate such that the adhesive layer on the substrate covers an area which is larger by between 50 μm and 1 mm than the border of the contact area of the microchip which the microchip contacts the adhesive layer by.

18. The method in accordance with claim 1, wherein a window film is provided with a recess and the window film is arranged on the layer compound such that the microchip is arranged within the recess, and wherein the recess is filled at least partly by a potting compound.

19. The method in accordance with claim 18, wherein another film, or a cover made of polymer, glass or metal, for covering the recess provided in the window film is arranged on that side of the window film facing away from the substrate.

20. The method in accordance with claim 1, wherein the microchip is a sensor chip configured to measure at least one of air pressure, temperature, humidity, gas, gas components, liquid flow or gaseous flow by means of the active region, or wherein the microchip is a sensor chip for a fluidic system, a bio sensor chip or a capacitive sensor chip contactable with a liquid or gas.

21. The method in accordance with claim 1, wherein the microchip is a sensor chip configured to measure radiation, in particular light, by means of the active region.

22. The method in accordance with claim 1, wherein the microchip is configured to emit radiation, in particular light, by means of the active region.

23. A package for a microchip, comprising:
a film substrate comprising a contact area for electrical chip contacting,
an adhesive layer applied onto the film substrate and covering the contact area at least in portions, and
a microchip comprising an active region arranged on the outside of the chip, wherein the microchip is in contact with the adhesive layer at least in portions,
wherein the film substrate and the adhesive layer comprise a joint continuous opening, and
wherein the microchip is arranged on the adhesive layer such that the active region is exposed through the opening.

24. The package in accordance with claim 23, wherein the contact area is sealed hermetically around the opening by means of the adhesive layer.

25. The package in accordance with claim 23, wherein the package additionally comprises a window film comprising a recess, and the window film is arranged on the film substrate such that the microchip is arranged within the recess, and wherein the recess is filled at least partly by a potting compound.

26. The package in accordance with claim 25, wherein another film or a cover made of polymer, glass or metal, for covering the recess provided in the window film is arranged on that side of the window film facing away from the film substrate.

27. The package in accordance with claim 23, wherein the joint continuous opening comprises a cross-section continuous in the adhesive layer and in the film substrate.
